(19) United States
(12) Patent Application Publication
(10) Pub. No.: US 2010/0271792 A1
(43) Pub. Date: Oct. 28, 2010

(54) ELECTRONIC COMPONENT PACKAGE AND METHOD OF MANUFACTURING THE SAME

(75) Inventors: Jin-Won Choi, Yongin-si (KR); Soon-Jin Cho, Suwon-si (KR); Hueng-Jae Oh, Suwon-si (KR); Seung-Wan Kim, Suwon-si (KR); Seon-Jae Mun, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/612,158

(22) Filed: Nov. 4, 2009

(30) Foreign Application Priority Data
Apr. 27, 2009 (KR) 10-2009-0036460

(51) Int. Cl. H05K 7/02; B23K 31/02

(52) U.S. Cl. 361/767; 228/164

(57) ABSTRACT

An electronic component package and a method of manufacturing the same are disclosed. The method can include: providing a board, on which a multiple number of pads are formed; forming a solder resist layer, in which an opening superimposing over all of the pads is formed, on the board; forming metal posts over the pads, respectively; mounting an electronic component on the board by bonding the electrodes to the metal posts; and forming an underfill resin layer in the opening such that the underfill resin layer is interposed between the electronic component and the board. The solder resist layer may function as a dam that prevents the underfill resin layer from leaking in lateral directions during the subsequent underfill process so that the additional processes, such as dispensing, etc., that were required for forming a separate dam can be omitted, and the process time and costs can be reduced.

### CROSS-REFERENCE TO RELATED APPLICATIONS

This application claims the benefit of Korean Patent Application No. 10-2009-0036460, filed with the Korean Intellectual Property Office on Apr. 27, 2009, the disclosure of which is incorporated herein by reference in its entirety.

### BACKGROUND

1. Technical Field

The present invention relates to an electronic component package and to a method of manufacturing the electronic component package.

2. Description of the Related Art

Due to trends in current electronic products towards smaller size, lighter weight, and greater functionality, the I/O density in the electronic component package is increasing. Accordingly, there are active research efforts under way on the BGA (ball grid array) package, which uses solder balls for mounting an electronic component on a printed circuit board, as well as the flip chip package, in which the connection distance between the electronic component and the printed circuit board is minimized to improve electrical properties.

However, in a BGA package or a flip chip package, cracks may easily occur in the solder portions. This is because, due to a difference in coefficient of thermal expansion between the electronic component and the printed circuit board, temperature changes may apply thermal stress on the solder balls located between the electronic component and the printed circuit board. As cracks in the solder portions may lower the reliability of the package, an underfill process and a dam-and-fill process may be employed.

Unlike regular semiconductor molding materials that totally envelop the electronic component, an underfill resin may be used in small amounts between the electronic component and the printed circuit board to serve as an adhesive for securing the electronic component and to absorb external impact.

The underfill resin may be injected by capillary action into the portion between the chip and the board and may afterwards be hardened by heating. However, when the underfill resin is thus heated, the fluidity of the underfill resin may be increased so that a part of the underfill resin may leak out from the space between the electronic component and the printed circuit board. Moreover, an excessive amount of underfill resin may generally be used to avoid having an insufficient amount of underfill resin fill the space between the electronic component and the printed circuit board. As such, there may be a high possibility of the underfill resin leaking.

Thus, in order to prevent the underfill resin from leaking, a dam may be formed in a dam-and-fill process. That is, a linear dam may be formed by continuously extruding epoxy resin, etc., using a dispenser.

However, when filling in the underfill resin between the electronic component and the printed circuit board, according to the underfill and dam-and-fill processes, the forming of the dam may be dependent on the nozzle of the dispenser so that the dam may be given an irregular width and a generally wavy shape because of the friction at the end of the nozzle. Also, if the bumps on the printed circuit board are made from solder paste, etc., the heat applied during the underfill process may cause damage to the bumps made of solder paste.

### SUMMARY

An aspect of the invention provides an electronic component package and a method of manufacturing the electronic component package, in which a separate dam for the underfill and the additional process involved in forming the dam are omitted, and in which damage to the bumps by the heat applied during the underfill process is prevented.

Another aspect of the invention provides a method of manufacturing an electronic component package. The method may include: providing a board, on which a multiple number of pads are formed; forming a solder resist layer, in which an opening is formed superimposed over all of the pads, on the board; forming metal posts over the pads, respectively; mounting an electronic component on the board by bonding the electrodes to the metal posts; and forming an underfill resin layer in the opening such that the underfill resin layer is interposed between the electronic component and the board.

The operation of forming the metal post can include: forming a resist, in which a hole is formed exposing the pad, on the board; and filling a conductive material in the hole.

The operation of filling the conductive material can be performed by plating.

Also, the method of manufacturing an electronic component package can further include an operation of forming a seed layer on the pad, before the operation of filling the conductive material.

The operation of mounting the electronic component can be performed by interposing a solder layer between the electrode and the metal post.

Still another aspect of the invention provides an electronic component package that includes: a board, on which a multiple number of pads are formed; a solder resist layer, in which an opening is formed superimposed over all of the pads, formed on the board; a multiple number of metal posts formed respectively over the pads; an electronic component mounted on the board by bonding electrodes to the metal posts; and an underfill resin layer formed in the opening such that the underfill resin layer is interposed between the electronic component and the board.

Here, the electronic component package can additionally include a seed positioned between the pad and the metal post.

Also, the electronic component package can include a solder layer positioned between the electrode and the metal post.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flow diagram illustrating an embodiment of a method of manufacturing an electronic component package according to an aspect of the invention.

FIG. 2 through FIG. 10 are diagrams illustrating the processes of a method of manufacturing an electronic component package according to an aspect of the invention.

FIG. 11 is a cross-sectional view illustrating an embodiment of an electronic component package according to an aspect of the invention.

FIG. 12 is a plan view illustrating an embodiment of an electronic component package according to an aspect of the invention.

### DETAILED DESCRIPTION

The electronic component package and method of manufacturing the same according to certain embodiments of the invention will be described below in more detail with reference to the accompanying drawings. Those elements that are the same or are in correspondence are rendered the same reference numeral regardless of the figure number, and redundant descriptions are omitted.

In the present disclosure, when an element is described to be “formed on” another element, the description not only refers to those cases in which the element is in direct contact with the other element, but also encompasses those cases in which another member is interposed between the two elements, with the elements placed in direct contact with the intermediary member.

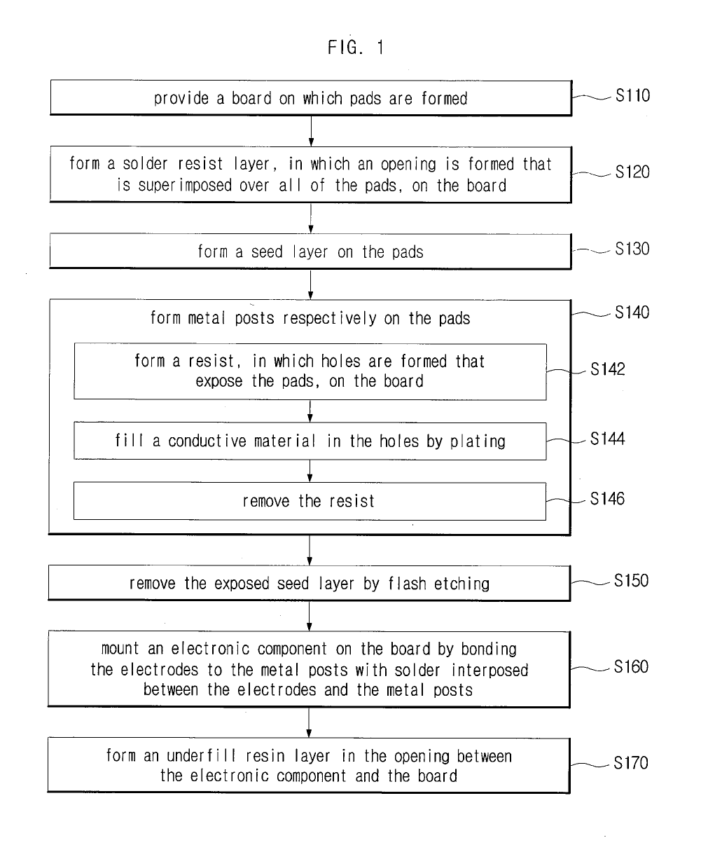

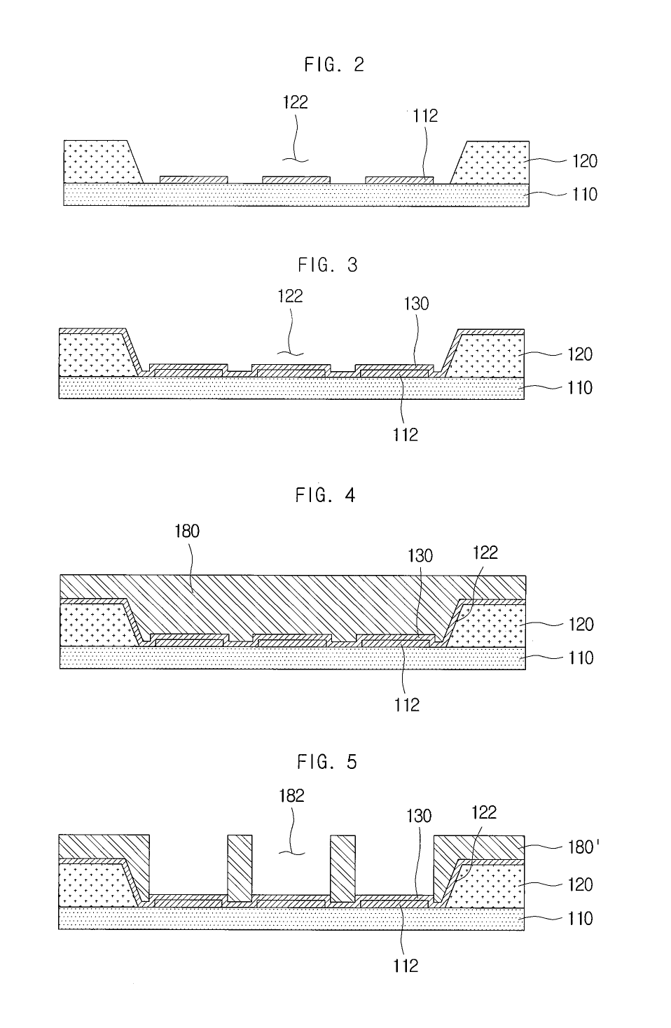

FIG. 1 is a flow diagram illustrating an embodiment of a method of manufacturing an electronic component package 100 according to an aspect of the invention, while FIG. 2 through FIG. 10 are diagrams illustrating the processes of an embodiment of a method of manufacturing an electronic component package 100 according to an aspect of the invention.

As illustrated in FIG. 1 through FIG. 10, an embodiment of the invention provides a method of manufacturing an electronic component package 100 that includes: providing a board 110 in which a multiple number of pads 112 are formed; forming a solder resist layer 120, in which an opening 122 that is superimposed over all of the pads 112 is formed on the board 110; forming a multiple number of metal posts 140 respectively on the multiple number of pads 112; mounting an electronic component 150 on the board 110 by bonding the electrodes 152 to the metal posts 140; and forming an underfill resin layer 170 in the opening 122 such that the underfill resin layer 170 is interposed between the electronic component 150 and the board 110.

According to this embodiment, an opening 122 may be formed in the solder resist layer 120 with the opening 122 superimposed over all of the pads 112 so that the solder resist layer 120 may function as a dam having a constant level, and the underfill resin layer 170 may be formed inside the opening 122. Thus, it is not necessary to form a separate dam for preventing leakage of the underfill resin layer 170 at the sides. As the extra processes for forming the dam, such as dispensing, etc., can be omitted, the process time and costs can be reduced.

The bumps for providing electrical contact between the board 110 and the electronic component 150 can be implemented as metal posts 140, to prevent the bumps from being damaged by the heat applied during the underfill process.

A more detailed description of each process will be provided below, with reference to FIG. 1 through FIG. 10.

First, as illustrated in FIG. 2, a board 110 in which multiple pads 112 are formed (S110) may be provided. The board 110 can be made of an insulating material, and pads 112 can be formed on the board 110. In addition, while it is not illustrated in the drawings, circuit patterns, etc., can also be formed on the board 110.

Next, as illustrated in FIG. 2, a solder resist layer 120 in which an opening 122 superimposed over all of the pads 112 is formed may be formed on the board 110 (S120). The solder resist layer 120, which is made of a photosensitive material, may be formed on the board 110, after which a single opening 122 that exposes all of the pads 112 may be formed by photolithography.

Thus, instead of forming a multiple number of openings in the solder resist layer 120 in correspondence to the respective positions of the pads 112, a single opening 122 that is superimposed over all of the pads 112 but has a constant level in relation to the board 110 may be formed so that the solder resist layer 120 may function as a dam that prevents the underfill resin layer 170 from leaking in lateral directions during the subsequent underfill process, in addition to its original function. Therefore, the additional processes such as dispensing, etc., that were required for forming a separate dam can be omitted, whereby the process time and costs may be reduced.

Next, as illustrated in FIG. 3, a seed layer 130 may be formed on the pads 112 (S130). That is, the seed layer 130 may be formed on the surface of the board 110, on which the pads 112 and the solder resist layer 120 are formed. In this way, the seed layer 130 may be formed on the pads 112 as well.

By thus forming the seed layer 130 on the pads 112 before forming metal posts 140, it is possible to form the metal posts 140 by electroplating. This can improve the strength of the metal posts 140, and at the same time improve thermal and electrical conductivity.

Next, as illustrated in FIG. 4 through FIG. 7, a multiple number of metal posts 140 may be formed respectively on the multiple number of pads 112 (S140). This process of forming metal posts 140 on the pads 112 as bumps for providing electrical connection to the electrodes 152 of the electronic component 150 can include the following operations.

First, as illustrated in FIG. 4 and FIG. 5, a resist 180′, in which holes 182 that expose the pads 112 are formed, may be formed on the board 110 (S142). As shown in FIG. 4, a resist 180′ made of a photosensitive material may be formed on the board 110, i.e. on the seed layer 130. Afterwards, as shown in FIG. 5, portions of the resist 180′ corresponding to the positions of the pads 112 may be removed by photolithography, to form a multiple number of holes 182 that expose the pads 112 to the exterior.

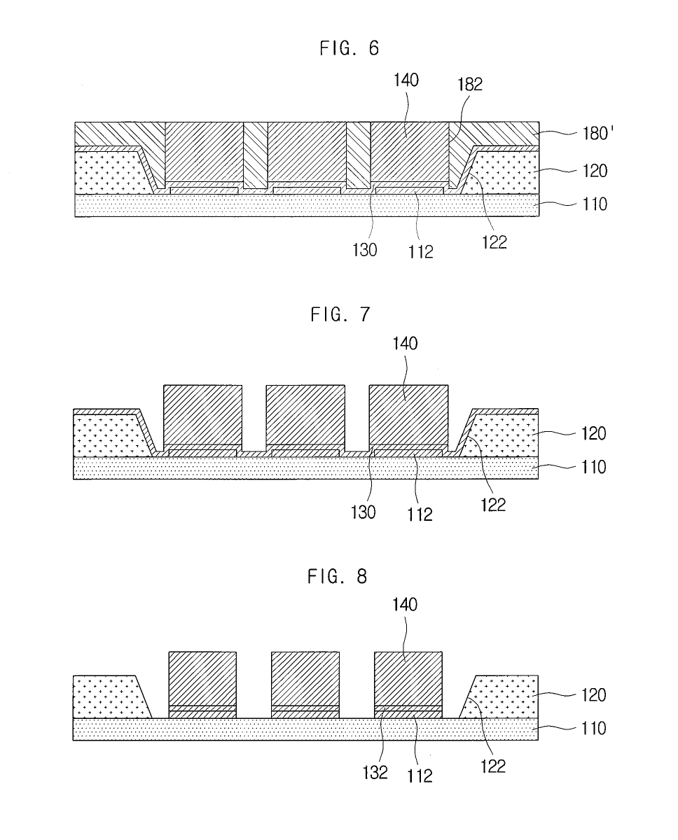

Then, as illustrated in FIG. 6, a conductive material may be filled inside the holes 182 by plating (S144). That is, by filling a conductive material, such as copper, etc., in each of the holes 182, the metal posts 140, which are electrically connected with the pads 112, may be formed.

Afterwards, as illustrated in FIG. 7, the resist 180′ may be removed (S146). After the metal posts 140 are formed, the resist 180′ may be removed to expose the seed layer 130 to the exterior.

In this particular embodiment, the bumps for implementing an electrical connection between the board 110 and the electronic component 150 may thus be formed as metal posts 140, and by forming the metal posts 140 from a material that has a higher melting point than that of the solder, damage to the bumps caused by the heat provided during the underfill process can be avoided.

Next, as illustrated in FIG. 8, the exposed seed layer 130 may be removed by flash etching (S150). Removing the exposed portions of the seed layer 130 through a flash etching process such that only the seeds 132 remain may prevent short-circuiting between the bumps. Here, along with the exposed portions of the seed layer 130, the surfaces of the metal posts 140 may also be partially removed.

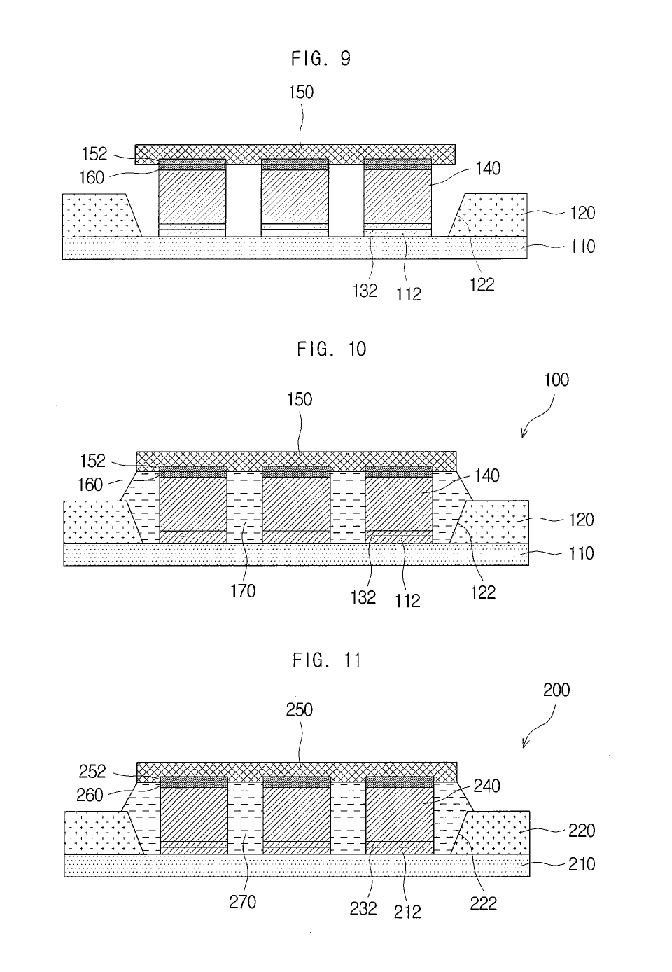

Next, as illustrated in FIG. 9, the electronic component 150 may be mounted on the board 110 by bonding the electrodes 152 to the metal posts 140 with a solder layer 160 interposed between the electrodes 152 and metal posts 140 (S160). This process is to mount the electronic component 150, such as a semiconductor chip, etc., on the board 110 by electrically connecting the electrodes 152 and the metal posts 140, where the electrodes 152 and the metal posts 140 may be bonded to each other for electrical connection, with a solder layer 160 placed between the electrodes 152 and the metal posts 140.

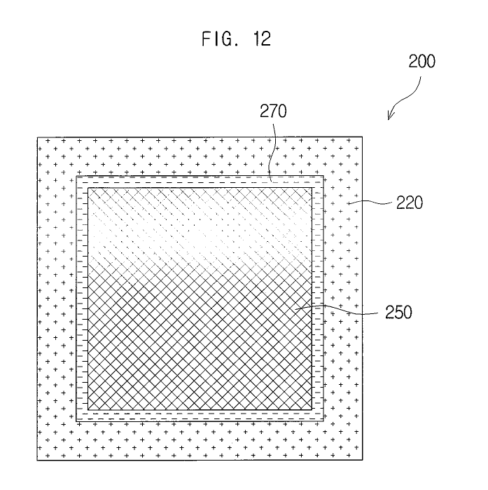

Next, as illustrated in FIG. 10, an underfill resin layer 170 may be formed in the opening 122 to be interposed between the electronic component 150 and the board 110 (S170). An underfill resin may be filled in the space defined longitudinally by the electronic component 150 and the board 110 and laterally by the opening 122, and afterwards the underfill resin may be heated to form the underfill resin layer 170.

The solder resist layer 120 may function as a dam, as already described above, so that when the underfill resin is injected inside the opening 122, the underfill resin may be confined by the side walls of the opening 122. Thus, the underfill resin layer 170 may effectively be filled between the electronic component 150 and the board 110, while the amount of resin protruding in the lateral directions of the board 110 may be minimized.

A description will now be provided, with reference to FIG. 11 and FIG. 12, on an embodiment of an electronic component package 200 according to an aspect of the invention.

FIG. 11 is a cross-sectional view illustrating an embodiment of an electronic component package according to an aspect of the invention, and FIG. 12 is a plan view illustrating an embodiment of an electronic component package according to an aspect of the invention.

As illustrated in FIG. 11 and FIG. 12, an embodiment of the invention provides an electronic component package 200 that includes: a board 210, in which a multiple number of pads 212 are formed; a solder resist layer 220, in which an opening 222 that is superimposed over all of the pads 212 is formed; a multiple number of metal posts 240 formed respectively on the multiple number of pads 212; an electronic component 250 mounted on the board 210 by bonding the electrodes 252 to the metal posts 240; and an underfill resin layer 270 formed in the opening 222 to be interposed between the electronic component 250 and the board 210.

According to this embodiment, an opening 222 may be formed in the solder resist layer 220 with the opening 222 superimposed over all of the pads 212 so that the solder resist layer 220 may function as a dam having a constant level and the underfill resin layer 270 may be formed inside the opening 222. Thus, it is not necessary to form a separate dam for preventing leakage of the underfill resin layer 270 at the sides.

The bumps for providing electrical contact between the board 210 and the electronic component 250 can be implemented as metal posts 240, to prevent the bumps from being damaged by the heat applied during the underfill process.

A more detailed description of each process will be provided below, with reference to FIG. 11 and FIG. 12.

The board 210 can be made of an insulating material, and a multiple number of pads 212 may be formed on the board 210, as illustrated in FIG. 11. Also, while it is not illustrated in the drawings, circuit patterns, etc., can be additionally formed on the board 210.

The solder resist layer 220, as illustrated in FIG. 11 and FIG. 12, may be formed on the board 210 and may include an opening 222 that is superimposed over all of the pads 212. That is, instead of having multiple openings 222 in correspondence to the positions of the pads 212, the solder resist layer 220 may include a single opening 222, which is superimposed over all of the pads 212 and which has a constant level with respect to the board 210.

Thus, the solder resist layer 220 may function as a dam that prevents the underfill resin layer 270 from leaking in lateral directions during the subsequent underfill process, in addition to its original function. Therefore, the additional processes, such as dispensing, etc., that were required for forming a separate dam can be omitted, whereby the process time and costs may be reduced.

The opening 222 may be formed by uncovering all of the multiple number of pads 212 by photolithography. This process has already been described above in the section presenting a method of manufacturing an electronic component package 100 (FIG. 10), and thus will not be described again.

The metal posts 240, as illustrated in FIG. 11, may be formed respectively on the multiple number of pads 212. A metal post 240 may be formed on each of the pads 212, to be electrically connected with the pad 212.

The bumps for implementing an electrical connection between the board 210 and the electronic component 250 may thus be formed as metal posts 240, and by forming the metal posts 240 with a material that has a higher melting point than that of the solder, damage to the bumps caused by the heat provided during the underfill process can be avoided.

Also, by forming the metal posts 240 with a material having low resistance, such as copper, etc., thermal and electrical conductivity can be improved. In this way, the properties of the electronic component package 200 in terms of signal transfer, heat release, and bending resistance can be improved, compared to existing arrangements that employ solder paste for forming the bumps.

The metal posts 240 can be formed by forming a multiple number of holes 182 (FIG. 6) in a resist 180′ (FIG. 6) formed on the board 210, and then filling the holes 182 (FIG. 6) with a conductive material, such as copper, etc. This process has already been described above in the section presenting a method of manufacturing an electronic component package 100 (FIG. 10), and thus will not be described again.

The seeds 232, as illustrated in FIG. 11, may be interposed between the pads 212 and the metal posts 240. That is, the seeds 232 may be formed on the pads 212, to be used for forming the metal posts 240 by electroplating.

As the metal posts 240 are formed by electroplating, using the seeds 232 formed on the pads 212, the strength of the metal posts 240, as well as thermal and electrical conductivity, can be improved.

After forming the metal posts 240 on a seed layer 130 (FIG. 6) formed on the pads 212 and removing the resist 180′ (FIG. 6), flash etching may be applied to the exposed seed layer 130, and the remaining portions may form the seeds 232. This process has already been described above in the section presenting a method of manufacturing an electronic component package 100 (FIG. 10), and thus will not be described again.

As illustrated in FIG. 11 and FIG. 12, the electronic component 250 may be mounted on the board 210 by bonding the electrodes 252 to the metal posts 240. That is, the electrodes 252 and the metal posts 240 may be electrically connected, whereby the electronic component 250, such as a semiconductor chip, etc., may be mounted on the board 210. Here, the electrodes 252 and the metal posts 240 may be bonded to each other for electrical connection, with a solder layer 260 interposed between the electrodes 252 and the metal posts 240.

The underfill resin layer 270 may be formed in the opening 222, to be interposed between the electronic component 250 and the board 210, as illustrated in FIG. 11 and FIG. 12. The underfill resin layer 270, which is filled in between the electronic component 250 and the board 210 to prevent the occurrence of cracks in the solder layer 260, may be filled in the opening 222 and confined by the side walls of the opening 222, so that the amount of underfill resin layer 270 protruding in the lateral directions of the board 210 can be minimized.

That is, the underfill resin layer 270 may be formed by filling an underfill resin in the space that is defined longitudinally by the electronic component 250 and the board 210 and laterally by the opening 222.

The solder resist layer 220 may function as a dam, as already described above, so that when the underfill resin is injected inside the opening 222, the underfill resin may be confined by the side walls of the opening 222. Thus, the underfill resin layer 270 may effectively be filled between the electronic component 250 and the board 210, while the amount of resin protruding in the lateral directions of the board 210 may be minimized.

While the spirit of the invention has been described in detail with reference to particular embodiments, the embodiments are for illustrative purposes only and do not limit the invention. It is to be appreciated that those of ordinary skill in the art can change or modify the embodiments, for example, by supplementing, altering, omitting, or adding elements, without departing from the scope and spirit of the invention.

What is claimed is:

1. A method of manufacturing an electronic component package, the method comprising:
providing a board having a plurality of pads formed thereon;
forming a solder resist layer on the board, the solder resist layer having an opening formed therein, the opening superimposed over all of the plurality of pads;
forming each of a plurality of metal posts over each of the plurality of pads, respectively;
mounting an electronic component on the board by bonding electrodes to the metal posts; and
forming an underfill resin layer in the opening such that the underfill resin layer is interposed between the electronic component and the board.

2. The method of claim 1, wherein the forming of the metal post comprises:
forming a resist on the board, the resist having a hole formed therein, the hole exposing the pad; and
filling a conductive material in the hole.

3. The method of claim 2, wherein the filling of the conductive material is performed by plating.

4. The method of claim 3 further comprising, before the filling of the conductive material, forming a seed layer on the pad.

5. The method of claim 1, wherein the mounting of the electronic component is performed by interposing a solder layer between the electrode and the metal post.

6. An electronic component package comprising:
a board having a plurality of pads formed thereon;
a solder resist layer formed on the board, the solder resist layer having an opening formed therein, the opening superimposed over all of the plurality of pads;
a plurality of metal posts formed respectively over the plurality of pads;
an electronic component mounted on the board by bonding electrodes to the metal posts; and
an underfill resin layer formed in the opening such that the underfill resin layer is interposed between the electronic component and the board.

7. The electronic component package of claim 6 further comprising a seed interposed between the pad and the metal post.

8. The electronic component package of claim 6 further comprising a solder layer interposed between the electrode and the metal post.
